(19) United States
(12) Patent Application Publication
(10) Pub. No.: US 2024/0347438 A1
(43) Pub. Date: Oct. 17, 2024

(54) PACKAGE STRUCTURE AND MANUFACTURING METHOD THEREOF

(71) Applicant: Powertech Technology Inc., Hsinchu County (TW)

(72) Inventor: Shang-Yu Chang Chien, Hsinchu County (TW)

(73) Assignee: Powertech Technology Inc., Hsinchu County (TW)

(21) Appl. No.: 18/632,221

(22) Filed: Apr. 10, 2024

(30) Foreign Application Priority Data
Apr. 13, 2023 (TW) 112113843

(51) Int. Cl. H01L 23/498; H01L 23/00; H01L 23/31; H01L 25/065

(52) U.S. Cl. CPC H01L 23/49838; H01L 23/3128; H01L 24/94; H01L 25/0655; H01L 24/16; H01L 24/32; H01L 24/73; H01L 2224/16225; H01L 2224/32225; H01L 2224/73204; H01L 2224/94; H01L 2924/1815

(57) ABSTRACT

A package structure including a redistributed circuit structure, a plurality of chips, a second encapsulant, a plurality of supporting members, a first encapsulant, and a plurality of connection terminals are provided. The redistributed circuit structure has a first surface and a second surface opposite thereto. The chips are disposed on the second surface of the redistributed circuit structure. The second encapsulant is disposed on the second surface of the redistributed circuit structure and covers the chips. The supporting members are disposed on the first surface of the redistributed circuit structure. The first encapsulant is disposed on the first surface of the redistributed circuit structure and covers the supporting members. The connection terminals are connected to the supporting members.

### CROSS-REFERENCE TO RELATED APPLICATION

This application claims the priority benefit of Taiwan application serial no. 112113843, filed on Apr. 13, 2023. The entirety of the above-mentioned patent application is hereby incorporated by reference herein and made a part of this specification.

### BACKGROUND

### Technical Field

The disclosure relates to a package structure and a manufacturing method thereof, and in particular relates to a package structure and a manufacturing method thereof having supporting members.

### Description of Related Art

With the advancement of science and technology, the requirements for electronic products in the market are becoming increasingly thinner, smaller, and more portable. Therefore, in a package structure including chips, how to reduce the overall thickness of the package structure and at least maintain the quality of the package structure has become a subject of current research.

### SUMMARY

A package structure is provided in the disclosure, the manufacturing process of the package structure is more efficient, simpler or has better yield, and the package structure may have better quality.

The package structure of the disclosure includes a redistributed circuit structure, a plurality of chips, a second encapsulant, a plurality of supporting members, a first encapsulant, and a plurality of connection terminals. The redistributed circuit structure has opposite first surface and second surface. The plurality of chips are disposed on the second surface of the redistributed circuit structure. The second encapsulant is disposed on the second surface of the redistributed circuit structure and covers the chips. The supporting members are disposed on the first surface of the redistributed circuit structure and embedded in the redistributed circuit structure. The first encapsulant is disposed on the first surface of the redistributed circuit structure and covers the supporting members. The connection terminals are connected to the supporting members.

A manufacturing method of a package structure of the disclosure includes the following operation. A redistributed circuit structure is formed on a carrier. A plurality of supporting structures and a first encapsulating material are formed on the redistributed circuit structure. A plurality of chips are disposed on the redistributed circuit structure. A second encapsulating material covering the chips are formed on the redistributed circuit structure. A portion of the second encapsulating material is removed to form a second encapsulant, a portion of the first encapsulating material is removed to form a first encapsulant, and a portion in each of the supporting structures is removed to form a plurality of supporting members after forming the second encapsulating material. A plurality of connection terminals connected to the supporting members are formed.

Based on the above, in the manufacturing process of the package structure of the disclosure, with the supporting structure and the first encapsulating material covered thereon (i.e., corresponding to the structural form in which the supporting member is embedded in the first encapsulant), the overall manufacturing process of the package structure may have a better yield, and the overall thickness of the package structure may be reduced or the quality of the package structure may be improved.

### BRIEF DESCRIPTION OF THE DRAWINGS

FIG. 1A to FIG. 1H are partial cross-sectional schematic diagrams of a partial manufacturing method of a package structure according to a first embodiment of the disclosure.

FIG. 1I is a partial cross-sectional schematic diagram of a package structure according to the first embodiment of the disclosure.

FIG. 1J is a partial cross-sectional schematic diagram of a package structure according to the first embodiment of the disclosure.

FIG. 2 is a partial cross-sectional schematic diagram of a package structure according to the second embodiment of the disclosure.

FIG. 3 is a partial cross-sectional schematic diagram of a package structure according to the third embodiment of the disclosure.

### DETAILED DESCRIPTION OF DISCLOSED EMBODIMENTS

Unless expressly stated otherwise, directional terms (e.g., up, down, top, bottom) as used herein are used for reference only to the drawings and are not intended to imply absolute orientation.

Unless expressly stated otherwise, any method described herein is in no way intended to be construed as requiring execution of its steps in a particular order.

The singular forms “a,” “the,” “said,” and similar terms include plural references unless expressly stated otherwise.

Similar terms such as “first”, “second”, and “third” may be used to describe various features, but these features should not be limited by these terms. These terms are used only to distinguish an feature from another, and do not define an order of execution or a structural orientation.

The disclosure is more fully described with reference to the drawings of this embodiment. However, the disclosure may be embodied in various different forms and should not be limited to the embodiments set forth herein only. The thickness, dimension, or size of layers or regions in the drawings may be exaggerated for clarity. The same or similar reference numerals denote the same or similar features, and the descriptions are not repeated in the following paragraphs.

The numerical value or the derivative relationship of the numerical value expressed in the specification (e.g., the comparison or trend of a ratio) may include the numerical value and the deviation value within the range of deviation acceptable to those skilled in the art. The above-mentioned deviation value may be one or more standard deviations in the manufacturing process or measurement process, or a calculation error caused by other factors such as the number of digits used, rounding, or error propagation during the calculation or conversion process.

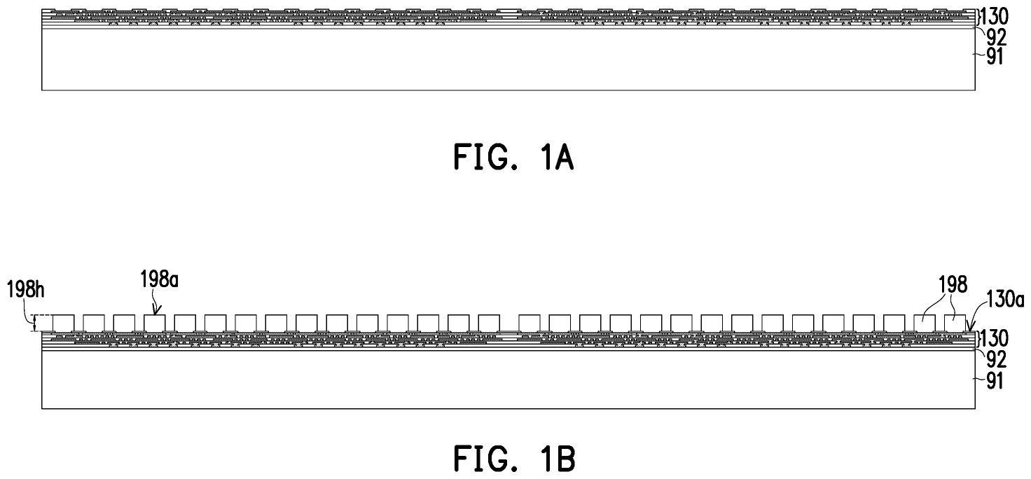

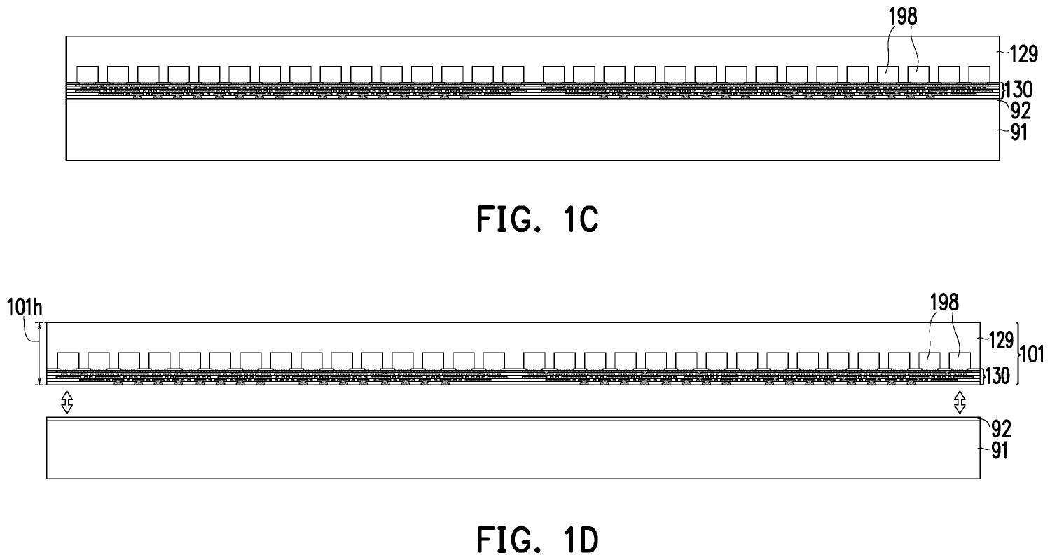

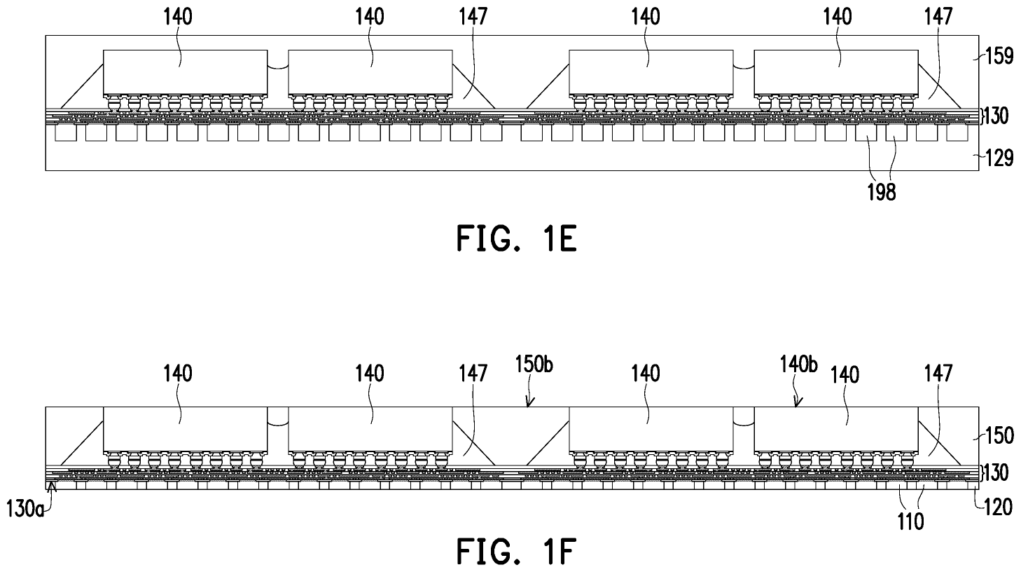

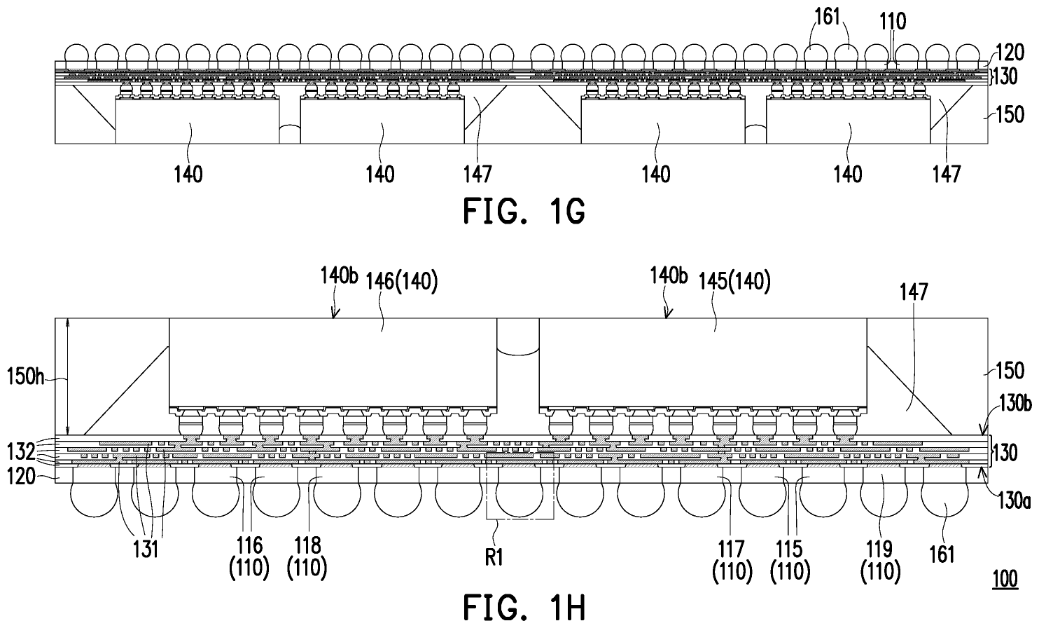

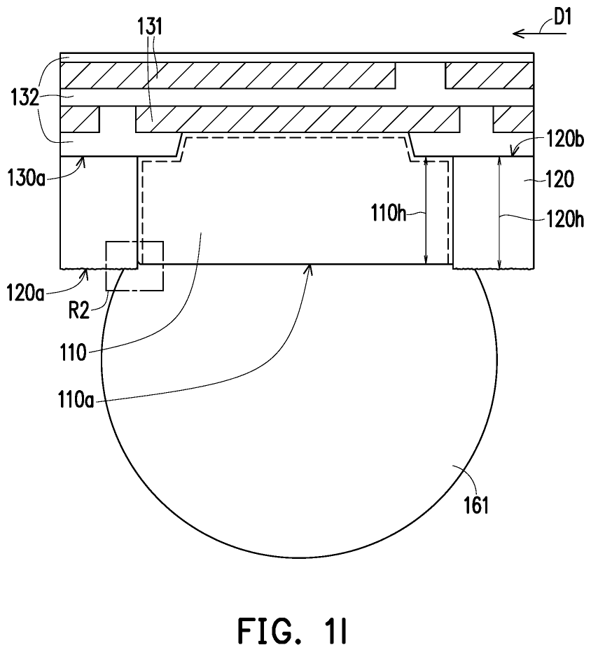

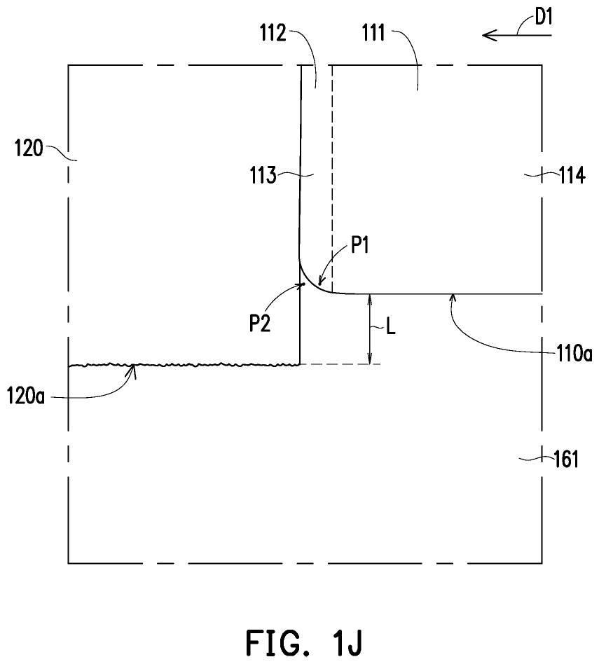

FIG. 1A to FIG. 1H are partial cross-sectional schematic diagrams of a partial manufacturing method of a package structure according to a first embodiment of the disclosure.

Referring to FIG. 1A, a redistributed circuit structure 130 is formed on a carrier 91. The disclosure has no special limitation on the carrier 91, as long as the carrier 91 is suitable for supporting the film layer formed thereon or the features disposed thereon.

In this embodiment, the carrier 91 may have a release layer 92, but the disclosure is not limited thereto. The release layer 92 is, for example, a light to heat conversion (LTHC) adhesive layer or other similar release layers, and the disclosure is not limited thereto.

The redistributed circuit structure 130 may include a conductive layer 131 (marked in FIG. 1I) and an insulating layer 132 (marked in FIG. 1H and/or FIG. 1I). The redistributed circuit structure 130 may be formed by commonly used semiconductor processes (e.g., a coating process, a deposition process, a lithography process, and/or an etching process), so details are not described herein. The conductive layer 131, the insulating layer 132 and/or the number of layers are not limited in the disclosure. In addition, in FIG. 1A or other similar drawings, the form of the conductive layer 131 and/or the insulating layer 132 is only shown as an example. For example, even though two adjacent conductive layers 131 are not connected in the cross section shown in FIG. 1A, they may still be connected in other cross sections that are not shown. A corresponding portion in the conductive layer 131 may form a corresponding circuit. In addition, the layout design of the aforementioned circuits may be adjusted according to design requirements, which is not limited in the disclosure.

In addition, in order to make the drawings concise and clear, the conductive layer 131 and/or the insulating layer 132 are not directly marked in FIG. 1A or other similar drawings. A portion of the conductive layer 131 and/or the insulating layer 132 in the redistributed circuit structure 130 may refer to FIG. 1H and/or FIG. 1I. In FIG. 1A or other similar drawings, the corresponding framed regions with slashed lines in the redistributed circuit structure 130 may be the corresponding conductive layer 131, and/or the corresponding blank framed regions in the redistributed circuit structure 130 may be the corresponding insulating layer 132.

In this embodiment, the topmost insulating layer 132 (i.e., the insulating layer 132 farthest from the carrier 91) may have an opening, and the opening may expose a portion of the topmost conductive layer 131 (i.e., the conductive layer 131 farthest from the carrier 91).

In an embodiment, the material of the insulating layer 132 of the redistributed circuit structure 130 is, for example, polyimide (PI), other suitable organic insulating materials, or a stack or combination thereof.

Referring to FIG. 1A to FIG. 1B, a plurality of supporting structures 198 are formed on the redistributed circuit structure 130.

In this embodiment, the supporting structure 198 may be formed by commonly used semiconductor processes (e.g., a lithography process, a sputtering process, an electroplating process, and/or an etching process), but the disclosure is not limited thereto.

In an embodiment, the supporting structure 198 may include a plating core layer and a seed layer surrounding the plating core layer. In an embodiment, the seed layer and/or the plating core layer may include a copper layer. For example, the seed layer may include a copper layer formed by a sputtering process, and the plating core layer may include a copper layer formed by an electroplating process.

In an embodiment not shown, a supporting structure which is similar to the supporting structure 198 may include a seed layer and a plating layer disposed on the seed layer. In an embodiment, the seed layer and/or the plating layer may include a copper layer. For example, the seed layer may include a copper layer formed by a sputtering process, and the plating layer may include a copper layer formed by an electroplating process.

In this embodiment, the supporting structure 198 may be embedded in the opening of the topmost insulating layer 132 to be connected to the topmost conductive layer 131. In this way, the subsequent structure (e.g., the final structure of the package structure 100 or a certain portion of the structure in the manufacturing process of the package structure 100) may be more stable.

In an embodiment, the distance (can be regarded as the thickness 198h of the supporting structure 198) between the first surface 130a (in FIG. 1B or other similar drawings, it may be an outer surface of the topmost insulating layer 132) of the redistributed circuit structure 130 and the top surface 198a of the supporting structure 198 may be greater than or equal to 50 micrometers (μm). In this way, the plurality of supporting structures 198 may be suitable as main supporting components in the subsequent overall structure (e.g., the subsequent intermediate structure).

In addition, for clarity, not all the supporting structures 198 are marked one by one in FIG. 1A or other similar drawings.

Referring to FIG. 1B to FIG. 1C, an encapsulating material 129 is formed on the redistributed circuit structure 130. The encapsulating material 129 may at least laterally cover the supporting structure 198.

For example, a molding compound (e.g., epoxy; not shown) may be formed on the redistributed circuit structure 130. Then, the aforementioned molding compound is cured by suitable means (e.g., heating, lighting, and/or standing) to form the encapsulating material 129. That is, the encapsulating material 129 may be formed of a molding compound.

In this embodiment, the supporting structure 198 may be formed on the redistributed circuit structure 130 first; then, the encapsulating material 129 at least laterally covering the supporting structure 198 is formed on the redistributed circuit structure 130.

In an embodiment not shown, a photo imageable dielectric (PID) may be formed on the redistributed circuit structure 130 first; then, a dielectric opening exposing the topmost conductive layer 131 is formed on the photosensitive dielectric material by at least a photolithography process; then, a supporting structure 198 connected to the topmost conductive layer 131 is formed in the aforementioned dielectric opening by a commonly used semiconductor process. That is, the encapsulating material 129 may be formed of a photosensitive dielectric material.

In an embodiment not shown, the encapsulating material 129 may expose the top surface 198a of the supporting structure 198.

Referring to FIG. 1C to FIG. 1D, the redistributed circuit structure 130 is separated from the carrier 91 (e.g., separated from the film layer (e.g., the release layer 92) on the carrier 91).

In an embodiment, the separated structure may be regarded as an intermediate structure 101.

In an embodiment, the redistributed circuit structure 130 may be separated from the carrier 91 first; then, a suitable dicing process may be performed on the aforementioned separated structure. As such, a plurality of structures (each structure including the corresponding encapsulating material 129 and supporting structure 198) regarded as intermediate structures 101 may be formed.

In an embodiment, a suitable dicing process may be performed on the structure on the carrier 91 to form a plurality of diced structures; then, the diced structures (each structure including the corresponding encapsulating material 129 and supporting structure 198) are separated from the carrier 91. As such, a plurality of structures be regarded as a plurality of intermediate structures 101 may be formed.

In an embodiment, the cut structure may have less warpage in the subsequent manufacturing process or the corresponding structure. Moreover, for the overall manufacturing process of the package structure 100, it may be possible to have a better yield.

In an embodiment, in terms of the overall volume of the encapsulating material 129 and the supporting structure 198, the volume of the supporting structure 198 may be 10% to 30% of the aforementioned overall volume. In this way, the bending or warping of the intermediate structure 101 may be reduced.

In an embodiment, the coefficient of thermal expansion (CTE) of the material of the encapsulating material 129 is less than the coefficient of thermal expansion of the material (including the material of the insulating layer 132 and the material of the conductive layer 131) of the redistributed circuit structure 130. In this way, when the heating step is performed on the redistributed circuit structure 130 (e.g., the heating step that may be performed when the chip is disposed or the encapsulating material 129 is cured), the overall thermal expansion of the intermediate structure 101 may be reduced to improve the process yield of the package structure 100 and the quality of the package structure 100. Additionally, for a method of manufacturing a package structure, the encapsulating material 129 or a layer formed thereby (e.g., an encapsulant 120 as shown in FIGS. 1F-1H) contributes to good warpage control after the redistributed circuit structure 130 being formed. For example, a thicker EMC may resist shrinkage of a dielectric or insulation layer (e.g., the insulation layer 132 of the redistributed circuit structure 130 as shown in FIG. 1I) as it is cured and cooled down to room temperature.

In an embodiment, the thickness 101h of the intermediate structure 101 may be greater than or equal to 150 micrometers (μm). In an embodiment, in subsequent manufacturing processes, the intermediate structure 101 may already have a good stress tolerance, which is suitable for carrying the film layer formed thereon or the features disposed thereon. That is, in subsequent manufacturing processes, the intermediate structure 101 may not be required to be placed on a carrier (e.g., a carrier that is the same as or similar to the carrier 91). In this way, the manufacturing process of the package structure 100 may be made more efficient or simpler.

Referring to FIG. 1D to FIG. 1E, a plurality of chips 140 are disposed on the redistributed circuit structure 130, so that the circuits in the chips 140 and the corresponding circuits in the redistributed circuit structure 130 (a portion of the conductive layer 131 of the redistributed circuit structure 130) are electrically connected.

For example, the intermediate structure 101 in FIG. 1D may be flipped upside-down, and then the chip 140 may be disposed on the redistributed circuit structure 130 by means of flip chip bonding. For example, the active surface of the chip 140 may face the redistributed circuit structure 130, and the chip connection pads of the chip 140 may be electrically connected to corresponding circuits in the redistributed circuit structure 130 through corresponding conductive connectors (e.g., solder balls).

Continue referring to FIG. 1E, in an embodiment, a filler 147 may be formed between the chip 140 and the redistributed circuit structure 130. The filler 147 is, for example, capillary underfill (CUF) or other suitable filling materials, but the disclosure is not limited thereto.

In an embodiment, the filler 147 may be regarded as a type of encapsulating material.

Continue referring to FIG. 1E, after disposing the plurality of chips 140 on the redistributed circuit structure 130, an encapsulating material 159 is formed on the redistributed circuit structure 130. The encapsulating material 159 at least laterally covers each chip 140.

In an embodiment, a molding compound (e.g., epoxy; not shown) may be formed on the redistributed circuit structure 130. Then, the aforementioned molding compound is cured by suitable means (e.g., heating, lighting, and/or standing) to form the encapsulating material 159.

Continue referring to FIG. 1E to FIG. 1F, a thinning step is performed on the structure shown in FIG. 1E to form the structure shown in FIG. 1F.

In an embodiment, a portion of the encapsulating material 159 (marked in FIG. 1E) may be removed to form a second encapsulant 150 (marked in FIG. 1F) laterally covering each chip 140. In an embodiment, a portion of the encapsulating material 159 (marked in FIG. 1E) may be removed by a suitable planarization step. In an embodiment, during the process of removing a portion of the encapsulating material 159 (marked in FIG. 1E), a portion of the chip 140 (e.g., the silicon substrate of the chip 140) may also be removed. In an embodiment, the top surface 150b of the second encapsulant 150 and the back surface 140b of the chip 140 are coplanar. The back surface 140b of the chip 140 is opposite to the active surface of the chip 140.

In an embodiment, a portion of the encapsulating material 129 (marked in FIG. 1E) and a portion of the supporting structure 198 (marked in FIG. 1E) may be removed to correspondingly form the first encapsulant 120 (marked in FIG. 1F) and the supporting member 110 (marked in FIG. 1F). In addition, for clarity, not all the supporting members 110 are marked one by one in FIG. 1E or other similar drawings.

In an embodiment, a portion of the encapsulating material 129 and a portion of the supporting structure 198 may be removed through the same step (e.g., the suitable planarization step).

In an embodiment, after removing a portion of the encapsulating material 129 and a portion of the supporting structure 198 through the same step (e.g., the suitable planarization step), a portion of the supporting structure 198 may also be further removed through etching (e.g., wet etching) to correspondingly form the first encapsulant 120 (marked in FIG. 1F) and the supporting member 110 (marked in FIG. 1F). In this way, during the process of removing a portion of the encapsulating material 129, the possibility of the used reagent (e.g., slurry or other possible abrasives) or the removed substance (e.g., insulating particles produced by the removed encapsulant) adhering to the supporting member 110 may be reduced, and in subsequent steps or structures, the connection quality or conductive quality between the supporting member 110 and other features may be improved. In addition, the supporting member 110 may be formed by methods including etching.

In an embodiment, the distance (which may be regarded as the thickness 110h of the supporting member 110; marked in FIG. 1I) between the first surface 130a (e.g., the outer surface of the bottommost insulating layer 132) of the redistributed circuit structure 130 and the surface 110a (marked in FIG. 1I) of the supporting member 110 may be basically less than the distance (can be regarded as the thickness 120h of the first encapsulant 120; marked in FIG. 1I) between the first surface 130a (i.e., the outer surface of the bottommost insulating layer 132) of the redistributed circuit structure 130 and the bottom surface 120a (marked in FIG. 1I; may be referred to as the second encapsulating surface) of the first encapsulant 120. In this way, an feature subsequently connected to the supporting member 110 may be regarded as being embedded in the first encapsulant 120, thereby improving the connection quality between the supporting member 110 and the feature.

In general semiconductor manufacturing, the surface pattern formed after a planarization step (e.g., grinding or polishing) of an object may be different from the surface pattern formed after an etching step (e.g., wet etching) of the object.

For example, if a planarization step is performed on an object, the surface formed may have grinding marks; alternatively, the generation or size of grinding marks may be reduced by the adjustment of the grinding rate, the adjustment of the grinding time, the selection of the grinding slurry, and/or the selection of the grinding pad. In addition, if an etching step is performed on an object, the surface formed may have an etching texture. That is, the surface roughness of the bottom surface 120a (marked in FIG. 1I) of the first encapsulant 120 may be different from the surface roughness of the surface 110a (marked in FIG. 1I; may be referred to as a supporting surface) of the supporting member 110.

In addition, during the wet etching step (which may include a wet cleaning step required after the wet etching step), there may be a bit of edge etching due to etchant residue on the edge and/or at the interface. For example, the surface 110a (which may be referred to as a supporting surface) of the supporting member 110 may be an etched surface, and the edges of the aforementioned etched surface may have a corresponding curvature. For another example, as shown in FIG. 1J, in terms of the surface 110a (which may be referred to as the second portion 112) of the supporting member 110 close to the first encapsulant 120, compared with other places (which may be referred to as the first portion 111 surrounded by the second portion 112) in the surface 110a of the supporting member 110, the surface 110a of the supporting member 110 near the first encapsulant 120 may be more concave toward the direction of the redistributed circuit structure 130. That is, the distance (which may be regarded as the thickness of the first portion 111) between the first surface 130a (i.e., the outer surface of the bottommost insulating layer 132) of the redistributed circuit structure 130 and the bottom end of the first portion 111 may be greater than the distance (which may be regarded as the thickness of the second portion 112) between the first surface 130a (i.e., the outer surface of the bottommost insulating layer 132) of the redistributed circuit structure 130 and the bottom end of the second portion 112.

In an embodiment, the distance L between the surface 110a of the supporting member 110 and the bottom surface 120a of the first encapsulant 120 may be less than or equal to 3 micrometers. For example, the distance between the surface 110a of the supporting member 110 and the bottom surface 120a of the first encapsulant 120 may be 1 micrometer to 2 micrometers.

Continue referring to FIG. 1F to FIG. 1G, the connection terminals 161 are formed on the supporting members 110. The connection terminal 161 may include a solder ball. For example, the structure shown in FIG. 1F may be flipped upside-down; then, the connection terminals 161 directly connected to the supporting members 110 are formed by a suitable method (e.g., a ball mounting process). In addition, for clarity, not all the connection terminals 161 are marked one by one in FIG. 1G or other similar drawings.

In an embodiment, the connection terminal 161 may directly contact the plating core layer 114 (marked in FIG. 1J) and the seed layer 113 (marked in FIG. 1J) of the supporting member 110.

In an embodiment not shown, a supporting member which is similar to the supporting member 110 may include a seed layer and a plating layer directly formed on the seed layer. The aforementioned may conformally cover the opening of the topmost insulating layer 132 (e.g., as shown in FIG. 1A) and the portion of the topmost conductive layer 131 exposed by the opening. In a direction along the thickness of the package, the seed layer is disposed between the plating layer and the redistributed circuit structure 130. Moreover, the connection terminal 161 may be in direct contact with the plating layer and not in direct contact with the seed layer.

In an embodiment, the material of the solder ball may include tin.

Referring to FIG. 1G to FIG. 1H, in an embodiment, a cutting step may be performed on at least the first encapsulant 120, the redistributed circuit structure 130, and the second encapsulant 150 to form a plurality of package structures 100 as shown in FIG. 1H. The cutting step is, for example, cutting with a rotating blade or a laser beam, but the disclosure is not limited thereto. It should be noted that the order of forming the connection terminals 161 and performing the cutting step is not limited in the disclosure. For example, in this embodiment, the connection terminals 161 are formed first; then, the aforementioned cutting step is performed. In an embodiment not shown, the aforementioned cutting step may be performed first; then, the connection terminals 161 are formed.

It is worth noting that after the cutting step is performed, similar feature reference numerals are used for the structure after the cutting step. For example, the second encapsulant 150 (as shown in FIG. 1G) may be a plurality of second encapsulants 150 (as shown in FIG. 1H) after cutting, the chips 140 (as shown in FIG. 1G) may be a plurality of chips 140 (as shown in FIG. 1H) after cutting, the redistributed circuit structure 130 (as shown in FIG. 1G) may be a plurality of redistributed circuit structures 130 (as shown in FIG. 1H) after cutting, the first encapsulant 120 (as shown in FIG. 1G) may be a plurality of first encapsulants 120 (as shown in FIG. 1H) after cutting, the supporting members 110 (as shown in FIG. 1G) may be a plurality of supporting members 110 (as shown in FIG. 1H) after cutting, and so on. Features in other package structures 100 follow the same feature reference numeral rules as above, and are not repeated or specifically shown herein.

The fabrication of the package structure 100 of this embodiment may be substantially completed after the above-mentioned manufacturing process.

FIG. 1H may be a partial cross-sectional schematic diagram of a package structure 100 according to the first embodiment of the disclosure. FIG. 1I is a partial cross-sectional schematic diagram of a package structure 100 according to the first embodiment of the disclosure. FIG. 1I may be an enlarged schematic diagram of the region R1 in FIG. 1H. FIG. 1J is a partial cross-sectional schematic diagram of a package structure 100 according to the first embodiment of the disclosure. FIG. 1J may be an enlarged schematic view of the region R2 in FIG. 1I. That is, if the package structure 100 is described, at least the contents and corresponding descriptions shown in FIG. 1H, FIG. 1I, and FIG. 1J should be considered. Of course, a portion of the structural details may be related to the above-mentioned manufacturing process. Therefore, if the package structure 100 is described, the contents and corresponding descriptions shown in FIG. 1A to FIG. 1H may further be considered.

Referring to FIG. 1G to FIG. 1J, the package structure 100 includes a redistributed circuit structure 130, a plurality of chips 140, a second encapsulant 150, a plurality of supporting members 110, a first encapsulant 120, and a plurality of connection terminals 161. The redistributed circuit structure 130 has a first surface 130a and a second surface 130b opposite thereto. The chip 140 is disposed on the second surface 130b of the redistributed circuit structure 130 (towards the upper side in FIG. 1H). The second encapsulant 150 is disposed on the second surface 130b of the redistributed circuit structure 130 (towards the upper side in FIG. 1H). The second encapsulant 150 at least directly or indirectly covers the chip 140 laterally. The supporting member 110 is disposed on the first surface 130a of the redistributed circuit structure 130 (towards the lower side in the drawing). The encapsulant 120 is disposed on the first surface 130a of the redistributed circuit structure 130 (towards the lower side in the drawing). The first encapsulant 120 laterally covers the supporting member 110. The connection terminal 161 is connected to the supporting member 110.

In an embodiment, as shown in the aforementioned drawings, during the manufacturing process of the package structure 100, the supporting structure 118 may be embedded in the encapsulating material 129 (i.e., corresponding to the structural form in which the supporting member 110 is embedded in the first encapsulant 120), and in the package structure 100, the thickness 150h of the second encapsulant 150 is greater than the thickness 120h of the first encapsulant 120. In this way, the overall manufacturing process of the package structure 100 may have better yield, and the overall thickness of the package structure 100 may be reduced.

In an embodiment, opposite ends of the supporting member 110 may respectively directly contact the connection terminal 161 and a portion of the bottommost (the bottommost in the direction shown in FIG. 1H) conductive layer 131 in the redistributed circuit structure 130. That is, the chip 140 may be electrically connected to the corresponding connection terminal 161 through the corresponding circuit (i.e., a certain portion of the conductive layer 131) in the redistributed circuit structure 130 and the corresponding supporting member 110. In this way, during the manufacturing process of the package structure 100, the supporting structure 118 (i.e., corresponding to the supporting member 110) and the encapsulating material 129 (corresponding to the first encapsulant 120) may serve as a structural support, and in the package structure 100, the supporting member 110 may be suitable as a portion of the transmission of electrical signals.

In an embodiment, for the packaging structure 100, the redistributed circuit structure 130 is a single and/or continuous structure. For example, in a top view, a projected area and/or peripheral profile of the redistribution structure 130 is substantially equal to a projected area and/or peripheral profile of the packaging structure 100.

In an embodiment, the material of the supporting member 110 is different from the material of the connection terminal 161. For example, the material of the supporting member 110 includes copper (Cu), and the material of the connection terminal 161 excludes copper. For example, the material of the supporting member 110 excludes tin, and the material of the connection terminal 161 includes tin (Sn).

In an embodiment, due to different materials and/or different manufacturing processes between the supporting member 110 and the connection terminal 161, there may be a corresponding interface or a eutectic region/a eutectic layer (e.g., Cu—Sn eutectic) between the supporting member 110 and the connection terminal 161.

In an embodiment, the thickness 120h of the first encapsulant 120 is greater than the thickness 110h of each supporting member 110, and/or a portion of each connection terminal 161 is embedded in the first encapsulant 120. That is, the bottom surface 120a of the first encapsulant 120 is not basically coplanar with the surface 110a of the supporting member 110. In this way, the connection terminals 161 may have better connection, and/or the possibility of ball drop during the manufacturing process or application process of the package structure 100 may be reduced.

In an embodiment, a portion of the supporting members 110 overlaps the chips 140. For example, the supporting member 115 (a portion of the supporting members 110) overlaps the chip 145 (a portion of the chips 140), and the supporting member 116 (a portion of supporting members 110) overlaps the chip 146 (a portion of the chips 140).

In an embodiment, the supporting member 117 (a portion of the supporting members 110) may be electrically connected to the chip 145, the supporting member 118 (a portion of the supporting members 110) may be electrically connected to the chip 146, and the supporting member 119 (a portion of supporting members 110) may be electrically separated from the chip 145 and the chip 146.

In an embodiment, the supporting member 119 may be a dummy component for signal processing or signal transmission of the package structure 100. That is, the supporting member 119 basically does not participate in signal processing or signal transmission.

It should be noted that the disclosure does not limit that the supporting member 119 is not electrically connected with any conductor. For example, in a possible embodiment, the supporting member 119 may be electrically connected to a shielding body through suitable circuitry. In this way, the overall charge capacity of the shielding body and the conductors electrically connected thereto (e.g., the supporting member 119) may be improved.

In an embodiment, taking FIG. 1J as an example, in the conductive region without any insulating material between the top surface 120b (marked in FIG. 1I; may be referred to as the first encapsulating surface) of the first encapsulant 120 and the bottom surface 120a (opposite to the top surface 120b; may be referred to as the second encapsulating surface) of the first encapsulant 120, in a direction D1 parallel to the top surface 120b or the bottom surface 120a of the first encapsulant 120, the aforementioned conductive region includes a first region P1 and a second region P2, and compared with the first region P1, the second region P2 is closer to the first encapsulant 120. The first region P1 includes at least one of the first metal element or the second metal element. In the first region P1, the first metal element relative to the second metal element (e.g., the relative molar number of the first metal element in the detection range or its derived unit/the relative molar number of the second metal element in the detection range or its derived unit; the same applies to the following) is a first ratio. The second region P2 includes at least one of the first metal element or the second metal element. In the second region P2, the first metal element relative to the second metal element is a second ratio. The first ratio is greater than the second ratio. The aforementioned types of metal elements or further corresponding concentrations thereof may be measured by a technique of elemental analysis (e.g., energy-dispersive X-ray spectroscopy (EDS/EDX), but not limited thereto).

In an embodiment, between the aforementioned first region P1 and the second region P2, the ratio of the first metal element to the second metal element may basically gradually decrease from the first region P1 to the second region P2. The gradient relationship between the aforementioned elements between the two regions may be measured, for example, by means of EDS/EDX line analysis.

It is worth noting that in a general measurement process (e.g., measurement belonging to elemental analysis), the corresponding measured value may have a corresponding measured fluctuation due to the measurement deviation (e.g., detection error or sampling point error) acceptable to a person having ordinary skill in the art. Therefore, in order to reduce the aforementioned measured fluctuation, it may be analyzed through multiple measurements or further data statistical processing (e.g., eliminating outliers and/or taking the average multiple times). For example, in order to confirm the relationship between elements in the two regions, it may be necessary to perform multiple measurements (e.g., 10, 30 or 50 times) between the two regions. Then, data statistical processing is performed on the results of the aforementioned multiple measurements to reduce the measured fluctuation and obtain the corresponding relationship.

In an embodiment, the first metal element is copper (Cu), and the second metal element is tin (Sn).

In an embodiment, the metal element ratio relationship between the first region P1 and the second region P2 may be (but not limited to) due to the edge/side etching phenomenon and/or the corresponding formation of intermetallic compound (IMC) during the manufacturing process of the package structure 100.

It is worth noting that in the previous five paragraphs, the term “element(s)” refers only to elements in the periodic table specifically.

In an embodiment, the package structure 100 may be referred to as a non-laminated substrate package. A general laminated substrate is, for example, an insulating substrate formed by laminating glass fiber, resin (e.g., epoxy resin, bismaleimide triazine resin (BT resin), polyphenylene ether resin (PPE resin), or other similar materials) and/or ceramics.

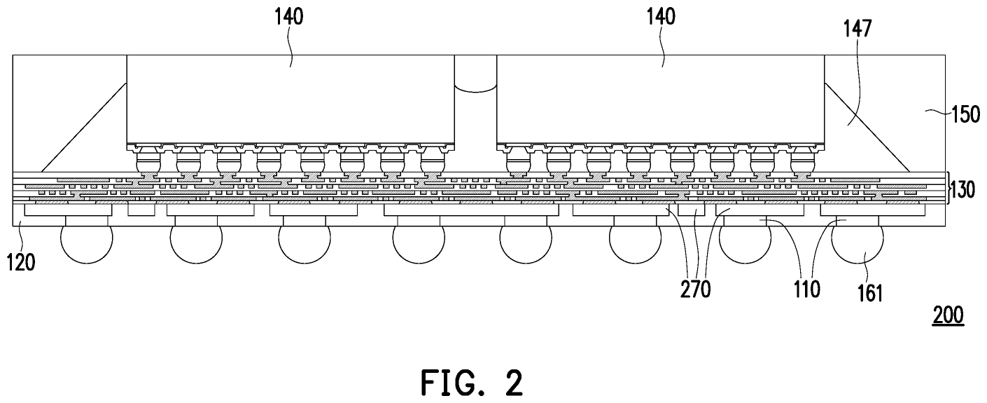

FIG. 2 is a partial cross-sectional schematic diagram of a package structure according to the second embodiment of the disclosure. The package structure 200 of this embodiment and its manufacturing method are similar to the package structure 100 and its manufacturing method of the first embodiment, and its similar components are denoted by the same reference numerals. The components have similar functions, materials or formation methods, and descriptions are omitted.

Referring to FIG. 2, the package structure 200 may include a redistributed circuit structure 130, a plurality of chips 140, a second encapsulant 150, a plurality of supporting members 110, a plurality of buffer members 270, a first encapsulant 120, and a plurality of connection terminals 161. The buffer member 270 may be disposed between the redistributed circuit structure 130 and the supporting member 110. The thickness of the buffer member 270 may be greater than the thickness of any conductive layer 131 in the redistributed circuit structure 130. The chip 140 may be electrically connected to the corresponding connection terminal 161 through the corresponding circuit (i.e., a certain portion of the conductive layer 131) in the redistributed circuit structure 130, the corresponding buffer member 270, and the corresponding supporting member 110.

In an embodiment, the buffer member 270 may include what is commonly referred to as a thick copper circuit. For example, during the manufacturing process of the package structure 200, the buffer member 270 may be formed on the redistributed circuit structure 130 by the same or similar formation method as the aforementioned supporting structure 198; then, the supporting member 110 is formed on the buffer member 270. In addition, for clarity, not all buffer members 270 are marked one by one in FIG. 2.

In an embodiment, a portion of the buffer member 270 may be electrically connected to the chip 140, and another portion of the buffer member 270 may be electrically separated from the chip 140.

In an embodiment, the portion of the buffer member 270 not electrically connected to the chip 140 may be a dummy component for signal processing or signal transmission of the package structure 200. That is, the portion of the buffer member 270 that is not electrically connected to the chip 140 basically does not participate in signal processing or signal transmission.

It should be noted that the disclosure does not limit that the portion of the buffer member 270 not electrically connected to the chip 140 is not electrically connected to any conductor. For example, in a possible embodiment, the portion of the buffer member 270 that is not electrically connected to the chip 140 may be electrically connected to a shielding body through suitable circuitry.

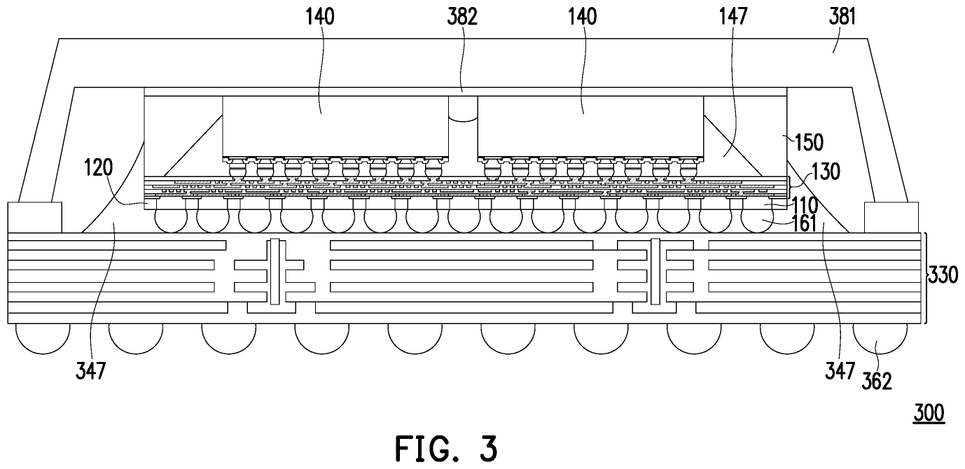

FIG. 3 is a partial cross-sectional schematic diagram of a package structure according to the third embodiment of the disclosure. The package structure 300 of this embodiment and its manufacturing method are similar to the package structure 100 and its manufacturing method of the first embodiment, and its similar components are denoted by the same reference numerals. The components have similar functions, materials or formation methods, and descriptions are omitted.

Referring to FIG. 3, the package structure 300 may include a redistributed circuit structure 130, a plurality of chips 140, a second encapsulant 150, a plurality of supporting members 110, a first encapsulant 120, a plurality of first connection terminals 161, a circuit board 330, a plurality of second connection terminals 362, and a housing 381. The first connection terminal 161 and the second connection terminal 362 may be respectively disposed on opposite sides of the circuit board 330. The housing 381 may be disposed on the circuit board 330. A plurality of chips 140 may be disposed in the accommodation space of the housing 381. In addition, for clarity, not all second connection terminals 362 are marked one by one in FIG. 3.

In this embodiment, the circuit board 330 may include a printed circuit board (PCB), a high density interconnect board (HDI board), an interposer, an ABF (Ajinomoto Build-Up Film) substrate, or other suitable boards including circuits, but the disclosure is not limited thereto. In addition, for clarity, only a portion of the circuits in the circuit board 330 are schematically shown in the drawings.

In this embodiment, the chip 140 may be electrically connected to the corresponding second connection terminal 362 through the corresponding circuit in the redistributed circuit structure 130, the corresponding supporting member 110, the corresponding first connection terminal 161, and the corresponding circuit in the circuit board 330.

In this embodiment, there may be an adhesive layer 382 between the chip 140 and the housing 381.

In this embodiment, the housing 381 may include a heat dissipation housing. For example, the adhesive layer 382 may be a thermally conductive adhesive layer. During the operation of the package structure 300, the chip 140 may be thermally coupled to the housing 381 through the thermally conductive adhesive layer, so that the heat generated by the chip 140 may be dissipated more efficiently.

In this embodiment, the housing 381 may include an electromagnetic interference shielding (EMI shielding) housing 381 or other similar shielding bodies.

In an embodiment, at least one of the supporting members 110 may be electrically connected to the housing 381 through a suitable circuit (e.g., the corresponding first connection terminal 161 and the corresponding circuit in the circuit board 330).

In an embodiment, a filler 347 may be formed between the first encapsulant 120 and the circuit board 330. The filler 347 is, for example, capillary underfill (CUF) or other suitable filling materials, but the disclosure is not limited thereto.

In an embodiment, the filler 347 may laterally cover the first encapsulant 120, the redistributed circuit structure 130, or the second encapsulant 150, but the disclosure is not limited thereto.

Components or features in all the drawings may become components presented in another drawing not shown through suitable arrangement and/or combination. In addition, additional components, features, and/or their corresponding functions may also be added without departing from the disclosure. For example, in a certain package structure, FIG. 1G may be a cross-sectional schematic diagram on a certain cross section, and FIG. 2 may be a cross-sectional schematic diagram on another cross section. For example, a certain component or feature shown in FIG. 3 may be added to the structure shown in FIG. 2.

To sum up, in the manufacturing process of the package structure of the disclosure, with the supporting structure and the encapsulating material covered thereon (i.e., corresponding to the structural form in which the supporting member is embedded in the encapsulant), the overall manufacturing process of the package structure may have a better yield, and the overall thickness of the package structure may be reduced or the quality of the package structure may be improved.

What is claimed is:

1. A package structure, comprising:
a redistributed circuit structure, having opposite first surface and second surface;
a plurality of chips, disposed on the second surface of the redistributed circuit structure;
a second encapsulant, disposed on the second surface of the redistributed circuit structure and covers the chips;
a plurality of supporting members, disposed on the first surface of the redistributed circuit structure and embedded in the redistributed circuit structure;
a first encapsulant, disposed on the first surface of the redistributed circuit structure and covers the supporting members; and
a plurality of connection terminals, connected to the supporting members.

2. The package structure according to claim 1, wherein a thickness of the second encapsulant is greater than a thickness of the first encapsulant.

3. The package structure according to claim 1, wherein opposite two ends of the supporting members directly contact the connection terminal and the redistribution circuit structure respectively.

4. The package structure according to claim 1, wherein a thickness of the first encapsulant is greater than a thickness of the supporting members.

5. The package structure according to claim 4, wherein each of the supporting members comprises a first portion and a second portion surrounding the first portion, and a thickness of the first portion is different from a thickness of the second portion.

6. The package structure according to claim 5, wherein a thickness of the first portion is greater than a thickness of the second portion.

7. The package structure according to claim 1, wherein a portion of the connection terminals is embedded in the first encapsulant.

8. The package structure according to claim 1, wherein:
the first encapsulant has opposite first encapsulating surface and second encapsulating surface;
the supporting members have a supporting surface;
the first encapsulating surface and the first surface of the redistributed circuit structure are coplanar; and
the second encapsulating surface and the supporting surface are not coplanar.

9. The package structure according to claim 8, wherein the supporting surface is not planar.

10. The package structure according to claim 8, wherein the supporting surface is an etched surface.

11. The package structure according to claim 1, wherein the first encapsulant has an encapsulating surface distant from the redistributed circuit structure, the supporting members have a supporting surface distant from the redistributed circuit structure, and a roughness of the encapsulating surface is different from a roughness of the supporting surface.

12. The package structure according to claim 1, wherein a portion of the supporting members overlaps the chips.

13. The package structure according to claim 1, wherein a portion of the supporting members is electrically connected to the chips, and a portion of the supporting members is electrically separated from the chips.

14. A manufacturing method of a package structure, comprising:
forming a redistributed circuit structure on a carrier;
forming a plurality of supporting structures and a first encapsulating material on the redistributed circuit structure;
disposing a plurality of chips on the redistributed circuit structure;
forming a second encapsulating material covering the chips on the redistributed circuit structure;
removing a portion of the second encapsulating material to form a second encapsulant, removing a portion of the first encapsulating material to form a first encapsulant, and removing a portion in each of the supporting structures to form a plurality of supporting members after forming the second encapsulating material; and
forming a plurality of connection terminals connected to the supporting members.

15. The manufacturing method of a package structure according to claim 14, further comprising:
separating the redistributed circuit structure and the carrier from each other before disposing the plurality of chips.
